(19) United States
(12) Patent Application Publication
(10) Pub. No.: US 2021/0035879 A1
(43) Pub. Date: Feb. 4, 2021

(54) ENCAPSULATED PACKAGE WITH CARRIER, LAMINATE BODY AND COMPONENT IN BETWEEN

(71) Applicant: Infineon Technologies AG, Neubiberg (DE)

(72) Inventors: Angela Kessler, Sinzing (DE); Thorsten Scharf, Lappersdorf (DE)

(73) Assignee: Infineon Technologies AG, Neubiberg (DE)

(21) Appl. No.: 16/943,054

(22) Filed: Jul. 30, 2020

(30) Foreign Application Priority Data
Aug. 2, 2019 (DE) 10 2019 121 012.7

(51) Int. Cl. H01L 23/31; H01L 23/498; H01L 21/48; H01L 21/56

(52) U.S. Cl. CPC H01L 23/3185; H01L 21/565; H01L 21/4821; H01L 23/49838

(57) ABSTRACT

A package and method of manufacturing a package is disclosed. In one example, the method comprises mounting at least one electronic component on a carrier, attaching a laminate body to the mounted at least one electronic component, and filling at least part of spaces between the laminate body and the carrier with mounted at least one electronic component with an encapsulant.

### CROSS-REFERENCE TO RELATED APPLICATION

This Utility Patent Application claims priority to German Patent Application No. 10 2019 121 012.7, filed Aug. 2, 2019, which is incorporated herein by reference.

### BACKGROUND

The present invention relates to a method of manufacturing a package, and a package.

A package may comprise an electronic component, such as a semiconductor chip, mounted on a carrier, such as a leadframe. Packages may be embodied as encapsulated electronic component mounted on a carrier with electrical connects extending out of the encapsulant and being coupled with an electronic periphery. In a package, the electronic component may be connected to the carrier by a clip or a bond wire.

However, package manufacture is still a process involving a high effort.

### SUMMARY

There may be a need to manufacture a package with low effort.

According to an exemplary embodiment, a method of manufacturing a package is provided, wherein the method comprises mounting at least one electronic component on a carrier, attaching a laminate body to the at least one electronic component, and filling at least part of spaces between the laminate body and the carrier with the mounted at least one electronic component in between with an encapsulant.

According to another exemplary embodiment, a package is provided which comprises a carrier, at least one electronic component mounted on the carrier, a laminate body attached to the at least one electronic component, and an encapsulant filling at least part of spaces between the laminate body and the carrier with the mounted at least one electronic component in between.

According to an exemplary embodiment, a package is provided which is a hybrid between a laminate structure and a carrier based structure. For example, the laminate body may comprise an organic material such as prepreg which may be interconnected with one or more metal layers such as copper foils to form a laminate. The carrier may for instance be a leadframe made of copper. Sandwiched in between the laminate body and the carrier may be an electronic component, such as a semiconductor chip. Such an arrangement may be placed at or in an encapsulation tool (for instance a molding tool) to thereby partially or entirely fill empty spaces in between with an encapsulant (such as a mold compound). Such a manufacturing architecture for manufacturing packages can be carried out with low effort for manufacturing multiple packages in parallel, thus obtaining a high throughput and low costs. At the same time, such a manufacturing architecture may allow combining the advantages of laminate technology and component mounting in accordance with carrier technology.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a block diagram illustrating a method of manufacturing a package according to an exemplary embodiment.

FIG. 2 illustrates a cross-sectional view of a package according to an exemplary embodiment.

FIG. 3 illustrates a cross-sectional view of a package according to another exemplary embodiment.

FIG. 4 to FIG. 8 illustrate cross-sectional views of structures obtained during manufacturing packages according to other exemplary embodiments which are shown in FIG. 7 and FIG. 8.

FIG. 9 illustrates a cross-sectional view of a package according to still another exemplary embodiment.

FIG. 10 illustrates a cross-sectional view of a package according to yet another exemplary embodiment.

FIG. 11 illustrates a cross-sectional view of a package according to still another exemplary embodiment.

FIG. 12 illustrates a cross-sectional view of a package according to yet another exemplary embodiment.

FIG. 13 illustrates a cross-sectional view of a package according to still another exemplary embodiment.

FIG. 14 illustrates a main surface of a batch of packages according to another exemplary embodiment, said main surface being covered by a copper foil.

FIG. 15 illustrates the main surface of the batch of packages according to FIG. 14 after removing the mentioned copper foil.

FIG. 16 illustrates a cross-sectional view of a package according to still another exemplary embodiment with encapsulated components having different vertical thickness.

FIG. 17 illustrates a cross-sectional view of a package according to yet another exemplary embodiment in which encapsulated components have different vertical thickness.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

The illustration in the drawing is schematically and not to scale.

In the following, further exemplary embodiments of the package and the method will be explained.

In the context of the present application, the term “package” may particularly denote an electronic device which may comprise one or more electronic components mounted on a carrier. Optionally, at least part of the constituents of the package may be encapsulated at least partially by an encapsulant.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated.

In the context of the present application, the term “encapsulant” may particularly denote a substantially electrically insulating and preferably thermally conductive material surrounding electronic component and part of carrier and/or laminate body to provide mechanical protection, electrical insulation, and optionally a contribution to heat removal during operation of the package.

In the context of the present application, the term “carrier” may particularly denote a support structure (preferably, but not necessarily being electrically conductive) which serves as a mechanical support for the one or more electronic components, and which may also contribute to the electric interconnection between the electronic component(s) and the periphery of the package. In other words, the carrier may fulfil a mechanical support function and optionally an electric connection function. Preferably, but not necessarily, the carrier may be partially or entirely electrically conductive.

In the context of the present application, the term “laminate body” may particularly denote a flat body (such as a sheet) formed by one or multiple interconnected laminate layers, i.e. layers which can be interconnected by lamination or which are interconnected by lamination. In particular, a laminate body may be a material that is suitable for sticking several laminate layers, for instance made of the same material, together. Hence, a laminate body may be a sheet shaped body made of one or multiple laminable or laminated layers. Said at least one laminate layer may be connected or configured to be connectable with other layers by lamination. Lamination may be a connection of laminable layers using elevated temperature, optionally accompanied by an additional mechanical pressure applied to stacked laminate layers. In particular, such a laminate body may be a pressed multilayer stack of one or more dielectric organic layers and/or one or more metallic foils. One or more dielectric laminate layers may be for example prepreg layers. Prepreg is a material which comprises a resin with glass fibres therein. The laminate body may also comprise one or more metal foils, which may be copper foils. More generally, the laminate body may comprise at least one dielectric layer which is capable of curing, polymerizing and/or cross-linking during a lamination process, thereby contributing to an adhesion force between multiple layers of a multilayer laminate.

In particular, a laminate material or material of the laminate body may be an epoxy resin or another polymer (like polyimide) or another insulating material filled with filler particles, in particular glass particles, more particularly glass fibers. Such a material may be provided as prepreg, i.e. as a sheet in which the epoxy resin is not or not fully cured, so that it can become liquid by supplying thermal energy. In a laminated body, such a prepreg sheet may be combined with one or more copper foils which can be attached upon lamination. Resin Coated Copper (RCC) is a combination of a copper foil and an uncured epoxy resin without glass fibers.

A gist of an exemplary embodiment is to form a hybrid package comprising a carrier (in particular a structured metal carrier, for instance made of copper, such as a leadframe) with attached one or more electronic components (in particular semiconductor dies) and with attached laminate body. An encapsulant (such as a mold compound) may be supplied through one or more openings of an encapsulation tool and of the carrier into a cavity which may already accommodate the laminate body (for instance comprising or consisting of a prepreg sheet, and optionally having a copper foil on the prepreg sheet).

In an embodiment, the carrier is a metallic (in particular structured, more particularly patterned or etched) carrier, in particular a leadframe. For example, the carrier may thus be a metallic plate which can be structured for instance by punching or etching so that a carrier with desired geometry may be obtained. The carrier may then be assigned to a respective laminate body and one or more mounted electronic components in between. Such a manufacturing architecture is compatible with an efficient batch production of multiple packages simultaneously.

In an embodiment, the carrier comprises a leadframe, in particular comprising a die pad and a plurality of leads. Such a leadframe may be a sheet-like metallic structure which can be patterned so as to form one or more die pads or mounting sections for mounting the one or more electronic components of the package. A leadframe may also comprise one or more lead sections for providing an electric connection of the package to an electronic environment when the electronic component(s) is/are mounted on the leadframe. In an embodiment, the leadframe may be a metal plate (in particular made of copper) which may be patterned, for instance by stamping or etching. Forming the carrier as a leadframe is a cost-efficient and mechanically as well as electrically advantageous configuration in which a low ohmic connection of the at least one electronic component can be combined with a robust support capability of the leadframe. Furthermore, a leadframe may contribute to the thermal conductivity of the package and may remove heat generated during operation of the electronic component(s) as a result of the high thermal conductivity of the metallic (in particular copper) material of the leadframe. A leadframe may comprise for instance aluminum and/or copper.

Alternatively, the carrier may be embodied as a patterned printed circuit board (PCB). One or more openings of the printed circuit board may be provided for enabling supply of liquid or viscous encapsulant material in spaces delimited between the at least one electronic component, the carrier and the laminate body.

In an embodiment, the laminate body comprises or consists of at least one prepreg layer. For instance, a dielectric material of the laminate body may be a glass fiber filled epoxy resin. Alternatively, the laminate body may comprise a Resin Coated Copper (RCC) sheet, i.e. a layer of resin (without glass fibers) and an attached copper foil. Further alternatively, the laminate body may comprise a BF (Build-up Film) layer, which is an epoxy composite material. An ABF layer shows excellent process efficiency, enables an easy handling and allows for a high freedom of design. However, other appropriate dielectric materials may be used as well for a dielectric portion of the laminate body.

In an embodiment, the laminate body comprises at least one copper layer on a sheet comprising a dielectric laminable material (for instance at least one prepreg layer). Prepreg layers are commercially available as large sheets which can be connected with one or multiple carriers of substantially the same size. A prepreg layer may be initially uncured for contributing to a connection with the one or more electronic components and/or the encapsulant during curing. By applying thermal energy, the prepreg layer may become adhesive and may therefore contribute to an interconnection between the constituents of the package. It is also possible that one or multiple prepreg layers are interconnected with one or more copper layers.

In an embodiment, the laminate body may comprise a copper layer. When using a laminate body having one or more copper layers, the copper layers may be used for providing electric interconnections with the electronic component and/or the carrier.

In an embodiment, the encapsulant is a mold compound. In other words, the filling of the spaces between laminate body and carrier with the one or more electronic components in between may be accomplished by molding. This is a simple technology which can be carried out with low effort and in a reliable way so as to fill the spaces with a mold type encapsulant. This improves the mechanical, electrical and thermal integrity of the package. When encapsulating by molding, injection molding or transfer molding may be carried out, for example. Vacuum molding may be preferred. For instance, a correspondingly encapsulated package (in particular electronic component with carrier and laminate) may be provided by placing said bodies between an upper mold tool and a lower mold tool and to inject liquid mold material therein. After solidification of the mold material, formation of the encapsulant is completed. If desired, the mold may be filled with particles improving its properties, for instance its heat removal properties. In other exemplary embodiments, the encapsulant may also be a casting component, or may be printed.

In an embodiment, the at least one electronic component comprises at least one pad exclusively on a main surface facing the carrier. Thus, the electronic component may be positioned with the one or more pads directly oriented in direction of the carrier to thereby establish a direct electrically conductive connection with the carrier. In another embodiment, the at least one electronic component comprises at least one pad exclusively on a main surface facing the laminate body. In said alternative, it is possible that the one or more pads are connected with electrically conductive material of the laminate body or extending through the laminate body. In still another embodiment, the at least one electronic component comprises at least one pad on a main surface facing the carrier and comprises at least one further pad on a main surface facing the laminate body. In said third alternative, pads may be both located face-up or face-down. This may be an option for instance with electronic components having a vertical current flow. For instance, the electronic component may be a transistor chip with gate pad and source pad on one main surface and drain pad on the opposing other main surface. The combination of laminate body technology and metallic carrier plate technology may therefore enable a simultaneous electric connection of pads face-up and face-down. It is also possible that the at least one electronic component has only one more pads oriented face-up or face-down.

In an embodiment, the encapsulant extends vertically beyond, in particular completely covers, a main surface of the carrier opposing another main surface of the carrier on which the at least one electronic chip is mounted. By taking this measure, the encapsulant itself may be used for accomplishing a cost-efficient isolation layer on top of the package which can be manufactured without additional effort.

In an embodiment, at least part of a main surface of the carrier opposing another main surface of the carrier on which the at least one electronic chip is mounted is exposed with respect to the encapsulant. By exposing at least part of a main surface of the package with respect to the encapsulant, it is simplified to electrically connect the readily manufactured package with an electronic environment, for instance with a mounting base (such as a printed circuit board, PCB) on which the package may be mounted. Furthermore, such exposed electrically conductive portions of the carrier may contribute to the heat removal and may thus be used as a cooling feature, which may be advantageous for instance in power semiconductor technology.

In an embodiment, the laminate body comprises a sheet comprising a dielectric material (for instance a prepreg sheet) and comprises a metal layer (for example a copper foil) on the sheet, and wherein the sheet is arranged between the metal layer and the at least one electronic component. For instance, a copper foil may be provided at a surface of the laminate body, and electric connections of the one or more electronic components may be arranged on the dielectric sheet, i.e. on the laminated side, rather than on the side of the metal layer.

In an embodiment, the package comprises at least one redistribution layer formed on and/or in the laminate body. In the context of the present application, the term “redistribution layer” may particularly denote a layer or arrangement of layers with electrically conductive and electrically insulating portions which accomplishes an interface function between the small dimensions of electronic components and larger dimensions of exterior package contacts. Forming such a redistribution layer on and/or in the laminate body may simplify a connection of the package with an electronic environment, such as a mounting base like a PCB.

In an embodiment, the package comprises at least one vertical electric connection element each extending through at least part of the encapsulant and through at least part of the laminate body. For instance, such a vertical electric connection element may electrically couple the laminate body with the carrier. More specifically, the package may comprise at least one vertical electric connection element extending through at least part of the encapsulant and through at least part of the laminate body and electrically coupling the above-described at least one redistribution layer with the carrier. For refining the electric interconnection within the hybrid package, electrically conductive posts or vias may be formed extending through at least part of the laminate body and/or at least part of the encapsulant. Thereby, even sophisticated electric coupling configurations may be achieved.

In an embodiment, at least 80% of one, in particular substantially one entire, main surface of the at least one electronic component is connected with the laminate body. When connecting a major portion or even substantially the entire main surface area of the at least one electronic chip with the laminate body, it may be safely prevented that filler particles of the mold compound may accumulate in a region between laminate body and electronic chip. This may prevent a deterioration of the integrity of the package and the accuracy of the mounting position and orientation of the electronic component on the laminate body.

In an embodiment, the thickness of the carrier is in a range between 20 μm and 3 mm, in particular in a range between 100 μm and 500 μm. A carrier with such dimensions may also have significantly larger length and width dimensions as compared to the thickness dimension and may thus have the shape of a plate.

In an embodiment, a thickness of the laminate body is in a range between 10 μm and 150 μm, in particular in a range between 20 μm and 40 μm. The laminate body may be thinner than the carrier.

In an embodiment, a thickness of the at least one electronic component is in a range between 15 μm and 1 mm, in particular in a range between 50 μm and 200 μm. The electronic component, for instance a semiconductor diode, may also be thinner than the carrier.

In particular, a thickness of the carrier may be larger than a thickness of the laminate body and may be larger than a thickness of the at least one electronic component. More particularly, the thickness of the carrier may be even larger than the thickness of the laminate body and the thickness of the at least one electronic component together. Thus, among carrier, laminate body and electronic component(s), the carrier may be by far the thickest body. This may conventionally cause problems in terms of thickness balancing. According to an exemplary embodiment, however, no such problems occur, since the encapsulant (in particular mold compound) allows to efficiently equilibrate height differences.

In an embodiment, the package comprises at least one further electronic component mounted on (in particular directly on) or above (for instance with one or more further structures in between) the encapsulant. In particular, said at least one further electronic component may be electrically coupled with the at least one encapsulated electronic component. Thus, the package may be configured as a system with multiple surface mounted and/or encapsulated electronic components. In particular, it may be possible to electrically couple the encapsulated electronic component with the surface mounted electronic component. By taking this measure, even complex electronic assemblies may be manufactured.

In an embodiment, the filling comprises molding, in particular vacuum molding. Filling spaces between laminate body, carrier and one or more component with a mold compound is a simple and reliable way of avoiding larger voids in the readily manufactured package. Vacuum molding is in particular advantageous in this context, since it keeps remaining voids particularly small. Descriptively speaking, the encapsulation tool (for instance mold tools enclosing carrier, laminate body and mounted electronic component(s)) may be provided with one or more openings for supplying precursor material of the encapsulant. The supplied precursor material of the encapsulant (for instance a liquid mold compound) may then be cured or hardened so as to form a solid encapsulant.

In another embodiment, the filling comprises printing, in particular one of the group consisting of ink-jet printing, stencil printing and screen printing. Thus, it is also possible to supply encapsulation material to an encapsulation tool according to the principle of ink-jet printing or screen printing. Also by printing, spaces in the structure between laminate body, carrier and electronic component(s) may be reliably filled with printed encapsulant material.

In an embodiment, the method comprises inserting the laminate body attached to the mounted at least one electronic component into an encapsulation tool to thereby delimit an encapsulation volume, injecting a precursor of the encapsulant into the encapsulation volume, and subsequently curing the precursor. To ensure compliance with this method, the carrier may be provided with one or more encapsulant openings enabling the precursor of the encapsulant to flow through said encapsulant openings and into the spaces. Thus, the method may comprise filling at least part of the spaces by supplying a precursor of the encapsulant through at least one opening extending through the carrier.

In an embodiment, the method comprises injecting the precursor into the encapsulation volume as a granulate. Providing the precursor of the encapsulation as a granulate may reduce or even eliminate the risk of bubble formation, as a liquid precursor may trap air before vacuum is applied. Thus, the use of a granulate as a precursor for the encapsulant may improve the mechanical and electrical integrity and performance as well as reliability of the manufactured package.

In an embodiment, the method comprises injecting the precursor with a volume being more flexible than a volume of the laminate body. Advantageously, the volume of the mold compound preform may be more flexible and elastic than the volume of the laminate body. As a result, issues such as void formation, strict leadframe design specification and limitations in terms of thickness of the electronic component may be solved.

In an embodiment, the method comprises manufacturing a plurality of packages by a batch fabrication. For instance, the carriers may be used with a size in the range from 50×150 mm² to 100×300 mm². The laminate body may be provided with typical panel sizes used in the PCB (printed circuit board) industry, for instance of 18 inch×24 inch or 21 inch×24 inch. Also a panel size of 600×600 mm² or more is possible. Of course, other dimensions are possible. It is also possible to combine a single laminate body sheet with multiple carrier structures, since standard dimensions of prepreg sheets may be larger than standard dimensions of leadframe type carriers. In other words, multiple packages may be formed simultaneously and thus with a high throughput on an industrial scale. In terms of such a batch manufacture, it is possible that multiple electronic components of multiple packages are sandwiched between laminate body and carrier. Thereafter, these multiple preforms of multiple packages may be encapsulated by an encapsulant in a common procedure, in an encapsulation tool. Further subsequently, electric connections may be formed for each of the packages, still being integrally connected. Thereafter, the so obtained structure may be separated into separate packages. Each of said packages may comprise a portion of the laminate body, a portion of the carrier and at least one of the electronic components as well as a portion of the encapsulant. Such a manufacturing process is highly efficient.

In an embodiment, the carrier comprises at least one encapsulation opening at least partially filled with the encapsulant. The encapsulation opening(s) of the carrier may be used for inserting a precursor of the encapsulant into the spaces during encapsulation. Such encapsulation openings may or may not form part of the readily manufactured package. For example, they may also be formed in sewing lines along which a structure comprising multiple packages to be separated is singularized after completing manufacture of the packages on panel level.

In a preferred embodiment, the package comprises an intermixed transition portion between the laminate body and the encapsulant comprising a mixture of material of the laminate body and the encapsulant. In particular, the intermixed transition portion may bridge or space pure laminate body material with respect to pure encapsulant material. In terms of the manufacturing process, this structural feature may correspond to carrying out the method so that, at the beginning of said filling, material of the encapsulant and material of the laminate body are both not yet cured. At the end of said filling, material of both the encapsulant and material of the laminate body may be fully cured. When curing (in particular polymerizing or cross-linking) material (such as epoxy resin) of both the encapsulant and the dielectric laminate body is triggered during encapsulation, flowing material of laminate body and encapsulant may intermingle or mix and may therefore form a mixed zone between pure encapsulant material and pure laminate body material. Highly advantageously, such a transition portion may strongly promote adhesion between encapsulant and laminate body. By taking this measure, the mechanical integrity of the package as a whole can be significantly improved. Advantageously, by intermingling, encapsulant and laminate body material may flow together during manufacturing to thereby form an integral inseparable structure, thereby significantly improving robustness of the manufactured package.

In particular, the intermixed transition portion may have a percentage of laminate body material and a percentage of encapsulant material, which percentages vary along a thickness direction of the intermixed transition portion. The percentage of encapsulant material may decrease from the pure encapsulant to the pure laminate body, whereas the percentage of laminate body may increase from the pure encapsulant to the pure laminate body. For instance, said percentages may continuously decrease and increase, respectively, between the pure encapsulant and the pure laminate body. Thus, the intermixed transition portion may show a gradient profile in terms of percentages of encapsulant and laminate materials.

In another embodiment, the package comprises an adhesion promoter at an interface between the laminate body and the encapsulant for promoting adhesion between material of the laminate body and material of the encapsulant. In such an embodiment, an adhesion promoting layer may enhance promotion between material of the encapsulant (in particular a mold compound) and material of the laminate body (in particular prepreg).

In an embodiment, the package comprises a plurality of electronic components. Preferably, the package may comprise electronic components with at least two different thicknesses mounted on the carrier. Multiple electronic components of the package may be interconnected by electrically conductive structures of laminate body and/or carrier, and optionally further interconnect structures. Since the package design and in particular its manufacturing method are properly compatible with multiple different components of different height, the flexibility of a circuit designer for realizing even complex electronic tasks may be advantageously increased. This increased flexibility results from the fact that encapsulant (in particular a mold compound) will flow into empty gaps, even those arising from electronic components of different height levels.

In an embodiment, the plurality of electronic components with the at least two different thicknesses are mounted on different vertical levels of the carrier. This may be accomplished in such a way that the upper main surfaces of the electronic components with different heights may be vertically aligned or vertically in flush with each other so as to be all in contact with the laminate body. For instance, this can be accomplished by inserting at least part of the electronic components in one or more recesses of the carrier for providing height balancing.

In another embodiment, only a part of the plurality of electronic chips with the at least two different thicknesses are mounted in contact with the laminate body. In such an embodiment, all electronic components may be mounted at the same vertical level at their bottom main surfaces which may be in contact with a flat carrier.

In a preferred embodiment, said filling is carried out after said attaching and after said mounting. This ensures that the encapsulant material may flow in all empty gaps between carrier, laminate body and the one or more electronic components in between.

In another embodiment, said filling is carried out before said attaching and after said mounting. Thus, the laminate body may be attached to the upper main surface of the carrier and the encapsulant after curing of the encapsulant has been completed.

In an embodiment, the package comprises a plurality of electronic components mounted on the carrier. Thus, the package may comprise multiple electronic components (for instance at least one passive component, such as a capacitor, and at least one active component, such as a semiconductor chip).

In an embodiment, a connection between the electronic component and the carrier is formed by a connection medium. For instance, the connection medium may be a solder structure, a sinter structure, a welding structure, and/or a glue structure. Thus, mounting the electronic component on the carrier may be accomplished by soldering, sintering or welding, or by adhering or gluing.

In an embodiment, the at least one electronic component comprises at least one of the group consisting of a controller circuit, a driver circuit, and a power semiconductor circuit. All these circuits may be integrated into one semiconductor chip, or separately in different chips. For instance, a corresponding power semiconductor application may be realized by the chip(s), wherein integrated circuit elements of such a power semiconductor chip may comprise at least one transistor (in particular a MOSFET, metal oxide semiconductor field effect transistor), at least one diode, etc. In particular, circuits fulfilling a half-bridge function, a full-bridge function, etc., may be manufactured.

As substrate or wafer for the semiconductor chips, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

Before exemplary embodiments will be described in more detail referring to the figures, some general considerations will be summarized based on which exemplary embodiments have been developed.

According to an exemplary embodiment, a package with a laminate body, at least one electronic component and a (preferably metallic) carrier may be provided in which gaps may be at least partially filled with an encapsulant. More specifically, a panel level mold-laminate body hybrid package may be provided.

In conventional molded packages, the package density per strip is limited by the standard leadframe strip size. With a modified approach of changing to a larger panel format and applying mainly batch processes, modified package concepts can be realized, which enable a reduction of the manufacturing effort. Additionally, chip embedding solutions with leadframe show competitive electrical and thermal performance, however the effort is hindering a broad use.

Conventional leadframe processes may be used in a backend production. Less packages per process stage can be produced, which leads to higher effort. Chip embedding packages may be produced in large panels, anyhow the manufacturing effort is high due to a high effort, where the lamination process and the structured material have a large share.

An exemplary embodiment provides a package in which a (in particular copper) carrier based package is provided with a hybrid character of mold and laminate material. Such a package can be produced in an efficient way with a large panel concept. The structural elements may be highly comparable to alternative chip embedding packages. Anyhow, the high effort with structured prepregs, their difficult adhesion, and laborious handling can be advantageously substituted by a molding (or other type of encapsulation) process. At the same time, a prepreg sheet or another laminate body may be used at a highly useful position to allow a thin layer on chip-top with very good mechanical performance.

According to an exemplary embodiment, it is advantageous that only one process is required for processing the metallic carrier and the laminate body. The material volumes and process flow can be advantageously adjusted in a way that most of a chip surface is covered by the laminate body material. This hinders large filler particles from a mold component or the like, which are difficult to remove later, to enter this area. Also the superior mechanical performance of the laminate body can be used at its best. On the other hand, the mold compound may fill up most of the exterior sides, to benefit from the process inherent flexible volume. Also the coefficient of thermal expansion (CTE) is much lower than for laminate bodies in z-direction (i.e. in vertical package direction), resulting in lower stress in the package.

A gist of an exemplary embodiment is to use a structured metal carrier (for example made of copper, for instance a leadframe) with attached die(s), mold through the openings into a cavity which already carries a laminate body (optionally having a copper foil on a prepreg sheet).

It should be mentioned that the below figures are not to scale. A typical thickness of a metal frame panel may be in a range from 20 μm to 3 mm, in particular 100 μm to 500 μm. Although exemplary embodiments can be implemented with very different package designs, a design of a package according to an exemplary embodiment may be a QFN package.

An assembly during manufacturing a component carrier can be done with at least one electronic component to be encapsulated in a face-up and/or a face-down configuration. A face-up embodiment may involve additional connections between the leadframe and a redistribution layer, which can for example be realized by laser drilling and plating to thereby form a vertical electrically conductive element. An embodiment with face-down orientation can be provided with an optional second redistribution layer. It is also possible to implement processes like solder masking, plating of solderable coatings, or solder balls or arrays.

Other embodiments can include single chips with vertical current flow and form packages similar to a TDSON, Blade3×3; or CanPak. Especially advantageous may be multichip components, such as half bridges (optionally with a driver) or full bridges or six-pack bridges (like DrBladex.x, PQFN, VQFN).

For such embodiments, multiple islands on the carrier metal may be used, optionally in face-up and face-down configuration, vias through laminate body and mold, and also a second redistribution layer. Additional layers can be added on one or both sides, if desired.

One or both sides of the package can be used, for instance, for the mounting of additional (for example passive and/or active) components.

The assembly or package of an exemplary embodiment can be used as an SMD (surface mounted device) component, but for the reason of the thin assembly also as a pre-assembled device for embedding inside a printed circuit board (PCB).

In different embodiments, also electronic components (such as any conductor chips) of different height can be encapsulated. In particular the thickest of said components may profit from the advantage of a direct contact to the laminate body.

For instance, a leadframe with an electronic component face-down may be provided on prepreg (being covered, if desired, by a copper foil), encapsulated (in particular molded) through one or more openings in the leadframe. Optionally, copper may then be removed.

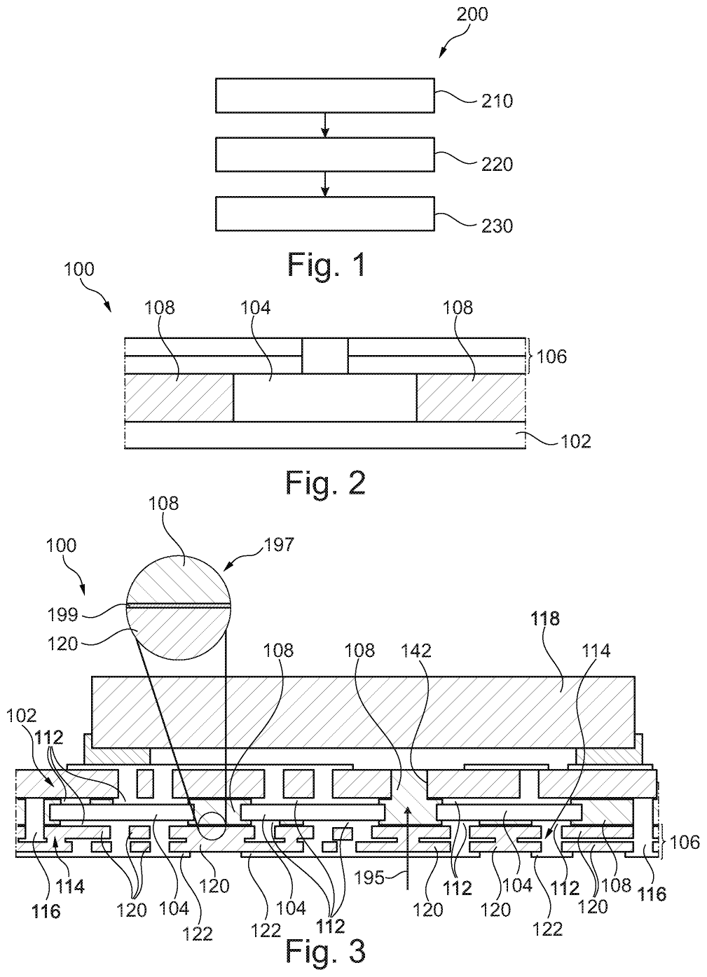

FIG. 1 illustrates a block diagram 200 illustrating a method of manufacturing a package 100 according to an exemplary embodiment. Reference signs used in the following concerning package 100 are taken from the embodiment of FIG. 2.

As shown in a block 210, the method comprises mounting an electronic component 104 on a carrier 102. A block 220 illustrates the process of attaching a laminate body 106 to the mounted electronic component 104. As shown by a block 230, the method further comprises filling at least part of spaces between the laminate body 106 and the carrier 102 with mounted electronic component 104 in between with an encapsulant 108.

FIG. 2 illustrates a cross-sectional view of a package 100 according to an exemplary embodiment.

The shown package 100 comprises a carrier 102. An electronic component 104 is mounted on the carrier 102. Furthermore, the package 100 comprises a laminate body 106 attached to the electronic component 104. Beyond this, an encapsulant 108 is provided which fills spaces between the laminate body 106 and the carrier 102 on which the electronic component 104 is mounted.

FIG. 3 illustrates a cross-sectional view of a package 100 according to another exemplary embodiment.

Package 100 of FIG. 3 comprises a further electronic component 118 surface mounted on the carrier 102 and electrically coupled with the encapsulated electronic components 104. More specifically, FIG. 3 illustrates an embodiment with a PCB (printed circuit board) as a carrier 102 which has at least one opening 142 for filling the space in between with material of encapsulant 108. This is indicated schematically by an arrow 195.

As illustrated in a detail 197, the package 100 comprises an advantageous but optional adhesion promoter 199 at an interface between the laminate body 106 and the encapsulant 108 for promoting adhesion between material of the laminate body 106 and material of the encapsulant 108.

Moreover, the package 100 is realized with a redistribution layer 114 and via connections. Package 100 according to FIG. 3 comprises vertical electric connection elements 116 extending vertically through the encapsulant 108 and through part of the laminate body 106. In the illustrated example, the laminate body 106 is composed of a prepreg layer 120 and one or more optional copper layers 122 attached to the prepreg layer 120. In the shown embodiment, the prepreg layer 120 is sandwiched between a copper layer 122 and the electronic components 104. As shown, the electronic components 104 each have a plurality of pads 112.

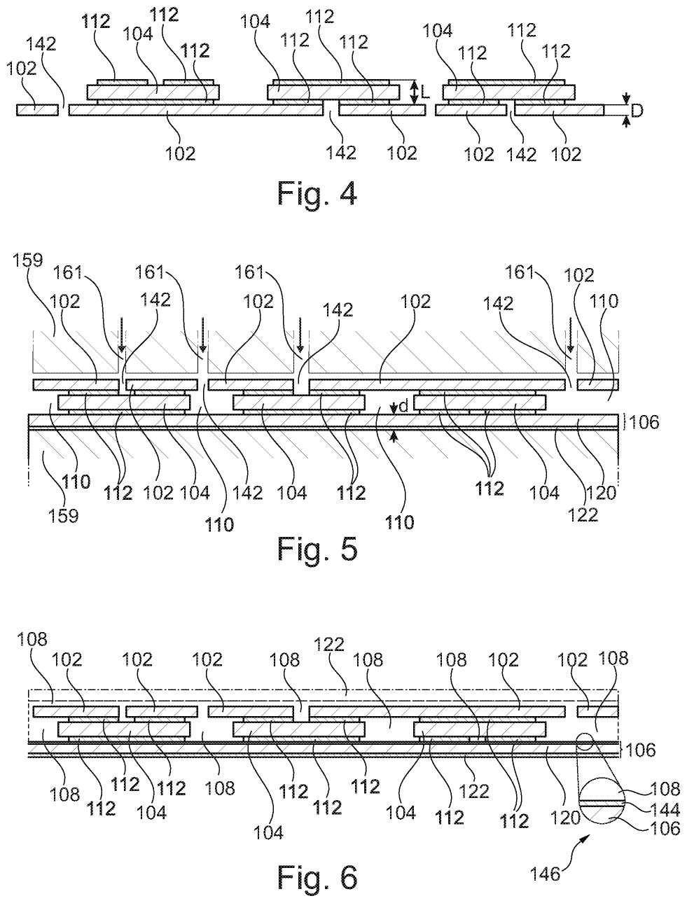

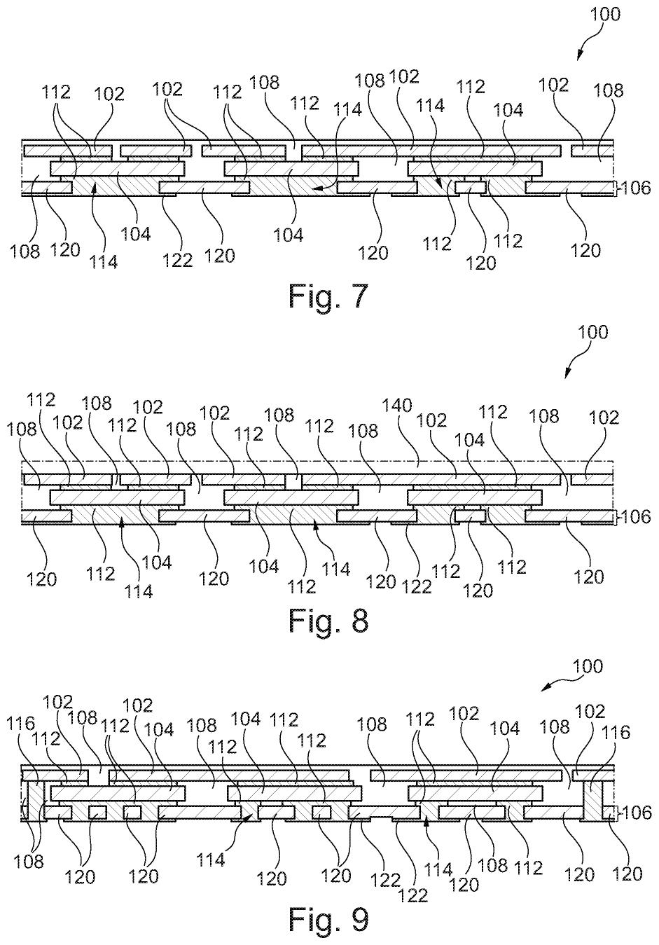

FIG. 4 to FIG. 8 illustrate cross-sectional view of structures obtained during manufacturing a package 100 according to another exemplary embodiment. The readily manufactured package 100 is illustrated in FIG. 7 and, in modified form, in FIG. 8.

Referring to FIG. 4, electronic components 104 are shown which are mounted on an electrically conductive carrier 102. In the shown embodiment, the electronic components 104 may be semiconductor power chips, more specifically transistor chips. Said electronic components 104 may each have three pads 112. More specifically, when embodied as MOSFET (metal oxide semiconductor field effect transistor) chip, each electronic component 104 may comprise on one main surface thereof a gate pad and a source pad. On an opposing main surface of the respective electronic component 104, a drain pad may be formed. During operation, each of the MOSFET type electronic components 104 may experience a vertical current flow, i.e. a flow of electric current in a vertical direction according to FIG. 4. A vertical thickness, L, of the electronic components 100 may for instance the 60 p.m. In the shown embodiment, all electronic components 104 may have the same vertical thickness, L. It is however alternatively also possible and perfectly compatible with the described manufacturing procedure that different electronic components 104 of the same package 100 have different vertical thicknesses, L. Height differences between different electronic components 104 may be balanced out by the molding process described referring to FIG. 5 and FIG. 6.

The shown carrier 102 may be a plate-shaped structured metal plate (for instance made of copper), such as a leadframe. A vertical thickness, D, of the carrier 102 may for instance be 0.5 mm. Thus, it can be seen that the figures are not true to scale. In many cases, carrier 102 will have a much larger thickness, D, than the thickness, L, of the electronic components 100. The connection between the carrier 102 and a respective pad 112 on the lower side of the respective electronic component 104 may be accomplished, for example, by soldering, sintering, welding or gluing.

Descriptively speaking, the structure shown in FIG. 4 may be obtained by carrying out a die attach of the electronic components 104 on the carrier 102 being embodied as a structured leadframe. The electronic component 104 on the left-hand side of FIG. 4 has the drain pad at a lower main surface thereof and the gate pad and the source pad on an upper main surface thereof. The electronic components 104 in the center and on the right-hand side of FIG. 4 have the drain pad at an upper main surface thereof and the gate pad and the source pad on a lower main surface thereof.

Still referring to FIG. 4, the carrier 102 comprises a number of encapsulation openings 142 through which, in a subsequent encapsulation process (compare the transition from FIG. 5 to FIG. 6), a liquid or viscous precursor of an encapsulant (see reference sign 108 in FIG. 6) may be inserted in gaps between the constituents shown in FIG. 4 and FIG. 5.

Referring to FIG. 5, the structure shown in FIG. 4 is turned around upside down (i.e. is rotated by 180°) and is then attached at its bottom side to laminate body 106. By taking this measure, the previously still exposed pads 112 of the electronic components 104 are attached to the laminate body 106.

Furthermore, FIG. 5 illustrates a thickness, d, of the laminate body 106 which may typically be in a range between 20 μm and 40 μm. Also referring to the above description of parameters D, L referring to FIG. 4, the largest of the three parameters d, D, L may be D, i.e. the thickness of the carrier 102. As a result of the subsequent encapsulation procedure described below, thickness differences can be balanced out by liquid or viscous encapsulation material flowing into gaps or spaces 110 between the various constituents of the structure shown in FIG. 5.

In the illustrated example, the laminate body 106 is composed of a prepreg layer 120 and an optional copper layer 122 attached to the prepreg layer 120. In the shown embodiment, the prepreg layer 120 is sandwiched between the copper layer 122 and the electronic components 104. More generally, the laminate body 106 may comprise an organic sheet, for instance comprising an epoxy resin, and may also comprise glass cloth for increasing the mechanical stability of the laminate body 106. One or more of such prepreg layers 120 may be provided. These one or more prepreg layers 120 may be interconnected with one or more copper layers 122 in accordance with a desired application.

As shown in FIG. 5, substantially an entire main surface of the electronic components 104 is connected with the laminate body 106. This has a positive impact on a subsequent encapsulation process (compare FIG. 6), and in particular may suppress undesired formation of voids in the interior of the manufactured package 100.

As shown, the arrangement of FIG. 5 may be placed as a whole in an encapsulation tool 159, such as a mold tool, for subsequent encapsulation. The shown arrangement of laminate body 106 attached to the mounted electronic components 104 may be inserted together into encapsulation tool 159 which delimits an encapsulation volume. Thereafter, an encapsulation procedure (in particular a molding procedure) may be carried out for preferably completely filling spaces 110 between the constituents 102, 104, 106 of the structure shown in FIG. 6 with an encapsulant 108, in particular a mold compound. For this purpose, a (for instance liquid or viscous) precursor of the encapsulant 108 may be supplied via one or more supply openings 161 of the encapsulation tool 159 and through the openings 142 in the carrier 102 into the spaces 110, see the arrows in FIG. 5.

Still referring to FIG. 5, the electronic components 104 may be simply attached on the prepreg layer 120 without curing the latter during this attachment procedure. It is however also possible that the electronic components 104 are attached to the prepreg layer 120 at an elevated temperature at which the material of the prepreg layer 120 is already sticky, so that a correct attachment of the electronic components 104 on the laminate body 106 can be promoted. Descriptively speaking, the electronic components 104 attached to the sticky prepreg layer 120 may sink into the prepreg layer 120, to thereby improve mechanical integrity. Said sinking of said electronic components 104 into said sticky prepreg layer 120 may also prevent relatively large filler particles of mold compound to reach the electronic component 104. This may safely prevent the electronic components 104 from being disturbed by mold material. Furthermore, a subsequent laser drilling procedure, for forming electric contacts for externally contacting the encapsulated electronic components 104 will not be disturbed by large mold particles.

FIG. 6 shows the result of the described encapsulation procedure. After having inserted the structure shown in FIG. 5 in the encapsulation tool 159 to thereby delimit an encapsulation volume, a precursor of the encapsulant 108 (in particular an uncured mold compound with filler particles, not shown) may be injected through the one or more holes 161 in the encapsulation tool 159 into the encapsulation volume. Subsequently, the precursor may be cured to thereby solidify and permanently fill the encapsulation volume, including said spaces 110, with the encapsulant 108. Preferably, in order to avoid the formation of voids, it is possible to inject the precursor into the encapsulation volume as a granulate. Moreover, it has turned out to be advantageous to inject the precursor into the encapsulation volume with a volume being more flexible than a volume of the laminate body 106. Preferably, the encapsulation process can be carried out by vacuum molding, in order to suppress formation of undesired voids in an interior of the encapsulant 108. As a result of the described encapsulation procedure, the spaces 110 between the laminate body 106 and the carrier 102 with the mounted electronic components 104 in between is filled with encapsulant 108, in the shown embodiment a mold compound.

As an alternative to the described molding procedure, it is also possible to accomplish encapsulation by ink jet printing through corresponding openings in an encapsulation tool.

Again referring to FIG. 6, mold compound on top of the carrier 102 may advantageously act as isolation layer and may allow a reliable dielectric encapsulation with low effort.

The materials involved in the described manufacturing process can be handled roll-to-roll, therefore fully automatic. It may be advantageous to use vacuum molding to get rid of entrapped air inside the leadframe type carrier 102. It has been demonstrated experimentally that the use of liquid mold compound in compression molding may, under undesired circumstances, bear the risk of bubble formation, as the liquid may entrap air before vacuum is applied. The use of granulate may allow overcoming this issue. It may also be advantageous that the volume of the mold compound is more flexible than the laminate body volume, suppressing or even eliminating issues like voiding, strict leadframe design specification, and chip thickness limitations.

As indicated in FIG. 6 as well, it is possible to attach a further metal layer, such as a further copper foil 122, on an upper main surface of the shown structure. Such a further copper foil 122 or other appropriate metal layer may improve the performance of the structure. For instance, said additional copper foil 122 or other appropriate metal layer may serve for electromagnetic shielding purposes of the readily manufactured package 100 and/or may simplify attachment of a cooling body (not shown) to the package 100, for instance by soldering or sintering.

As shown in a detail 146 in FIG. 6, the illustrated structure (and thus the readily manufactured package 100) may comprise an intermixed transition portion 144 at an interface between the prepreg 120 of the laminate body 106 and the mold type encapsulant 108. The intermixed transition portion 144 may comprise a mixture of pure material of the laminate body 106 and pure material of the encapsulant 108. Said intermixed transition portion 144 is highly advantageous, since it significantly improves the adhesion between material of the encapsulant 108 and material of the laminate body 106. The mentioned intermixed transition portion 144 may be created by adjusting the manufacturing process as follows: At the beginning of the filling or encapsulation procedure of filling or encapsulating the spaces 110 with material of encapsulant 108, material of the encapsulant 108 and material of the laminate body 106 may be both not yet cured. In other words, both the material of the encapsulant 108 and the prepreg material of the laminate body 106 may still be capable of becoming flowable by supplying thermal energy, so that the material of the encapsulant 108 and the prepreg of the laminate body 106 may become liquid or viscous, may start cross-linking, polymerizing and/or curing and may thereby become mixed in the intermixed transition portion 144 before becoming finally solid. For the reason of improving intra-package adhesion, it may also be preferred to first form the structure according to FIG. 5 and subsequently carrying out the molding and curing procedure.

Referring to FIG. 7, a redistribution layer 114 may be formed partially on and partially in the laminate body 106. This may involve patterning of the copper layer 122 of the laminate body 106. This may also involve forming openings in the prepreg layer 120 for exposing the pads 112 on the lower main surface of the electronic components 104. Subsequently, obtained holes may be filled with an electrically conductive material such as copper, for instance by plating. For instance, the redistribution layer 114 may be formed using a lithography process followed by copper plating. Also vias can be formed, if desired or required. As a result, the redistribution layer 114 is obtained which serves for bridging the smaller dimensions of the chip pads 112 with respect to the larger dimensions of the exterior contact surfaces of the package 100.

If no exposed electrically conductive surfaces are required or desired at the upper main surface, the structure shown in FIG. 7 can already be used as a package 100 according to an exemplary embodiment.

Referring to FIG. 8, it is however alternatively possible to expose upper main surfaces of the carrier 102 by removing material of the encapsulant 108 above the carrier 102. The result of such a process of exposing upper main surfaces of the carrier 102 by removing encapsulant material, for instance by grinding or milling, is shown in FIG. 8.

The illustrated package 100 comprises the electrically conductive carrier 102 which is here embodied as copper leadframe. MOSFET type power semiconductor electronic components 104 are mounted on the carrier 102, for instance by soldering, sintering, welding or gluing. The prepreg based laminate body 106 is attached to the pads 112 on the opposite side of the electronic components 104 and provides the basis of redistribution layer 114. Mold type encapsulant 108 fills gaps or spaces 110 between the laminate body 106 and the carrier 102 with the electronic components 104 in between.

The package 100 shown in FIG. 8 may be obtained by exposing electrically conductive and thermally conductive structures on both opposing main surfaces of package 100, for instance by grinding. As a result, a package 100 with double-sided cooling may be obtained, i.e. capable of removing heat created in interior of the package 100 during operation via both opposing main surfaces.

As indicated schematically in FIG. 8, it is possible to provide an additional electrically insulating and thermally conductive layer 140 on top of package 100, i.e. partially covering carrier 102 and partially covering encapsulant 108. For instance, such an additional electrically insulating and thermally conductive layer 140 may be a thermal interface material (TIM), optionally comprising filler particles for enhancing thermal conductivity of the TIM.

Although the manufacture of only one package 100 has been described referring to FIG. 4 to FIG. 8, it should be appreciated that the described manufacturing architecture can be carried out for manufacturing a plurality of packages 100 partially or entirely simultaneously by a batch fabrication. For this purpose, the above described carrier 102 can be provided for multiple such packages 100 in common. Correspondingly, the above described laminate body 106 can be provided in a size being sufficient for manufacturing multiple such packages 100 in common, i.e. on panel format. After having processed such a panel level laminate body 106 together with one or more carriers 102 and multiple electronic components 104, and after having encapsulated such a structure by a common encapsulation procedure, the obtained structure may be separated into multiple individual packages 100. This can be accomplished, for example, by sawing, laser cutting or etching. As a result, it is possible to manufacture multiple packages 100 with high throughput on an industrial scale and thus with low effort.

Although not shown, the obtained packages 100 may for instance be connected on a mounting base, such as a printed circuit board (PCB).

FIG. 9 illustrates a cross-sectional view of a package 100 according to another exemplary embodiment. Package 100 according to FIG. 9 comprises vertical electric connection elements 116 extending vertically through the carrier 102 and through the laminate body 106. In FIG. 9, the vertical electric connection elements 116 are copper plated vias. In the shown embodiment, the vertical electric connection elements 116 electrically couple the redistribution layer 114 with the carrier 102.

FIG. 9 shows a package 100 according to another exemplary embodiment which is configured as a half-bridge. For this purpose, the structuring of the redistribution layer 114 can be further refined. In the embodiment of FIG. 9, the electronic component 104 on the left-hand side is configured as a low-side MOSFET chip, the electronic component 104 in a central portion is configured as a high-side MOSFET chip and the electronic component 104 on the right-hand side is configured as a driver chip. Thus, the electronic component 100 according to FIG. 9 is a half-bridge with driver realized with redistribution layer 114 and via connection in form of vertical electric connection elements 116.

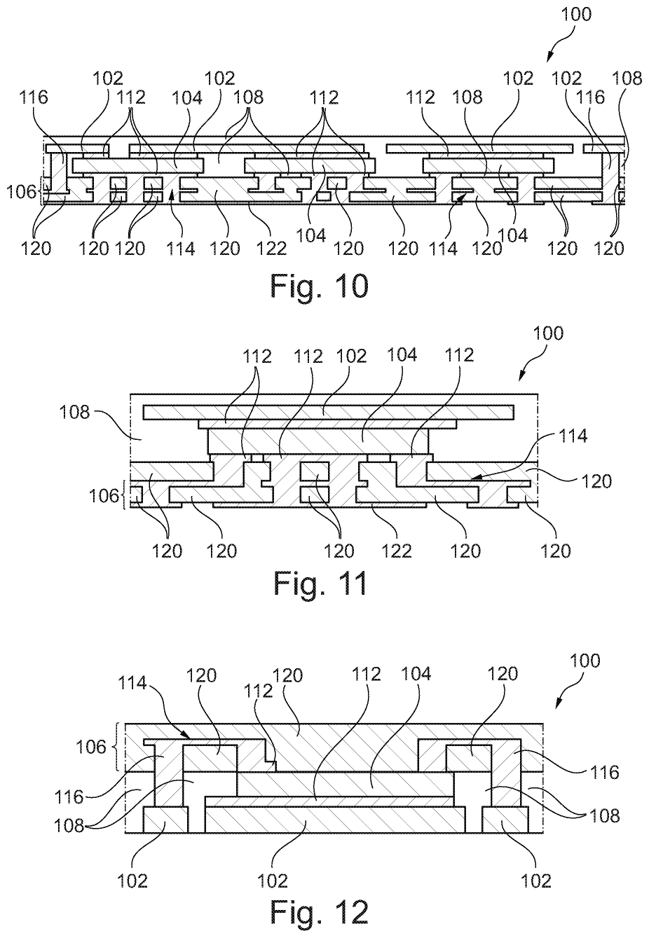

FIG. 10 illustrates a cross-sectional view of a package 100 according to another exemplary embodiment. FIG. 10 shows the example of a half bridge with driver chip realized with redistribution layers 114 and via connection, see the vertical electric connection elements 116 connecting laminate body 106 with carrier 102. FIG. 10 thus shows an embodiment with an additional redistribution layer 114, i.e. two redistribution layers 114 on the bottom portion of the package 100.

FIG. 11 illustrates a cross-sectional view of a package 100 according to another exemplary embodiment. This embodiment illustrates a QFN-style package 100 as mold-laminate hybrid.

FIG. 12 illustrates a cross-sectional view of a package 100 according to still another exemplary embodiment. FIG. 12 shows a configuration in which vertical electric connection elements 116 are implemented to connect the lower main surface with the laminate body 106 on the top main surface of the package 100.

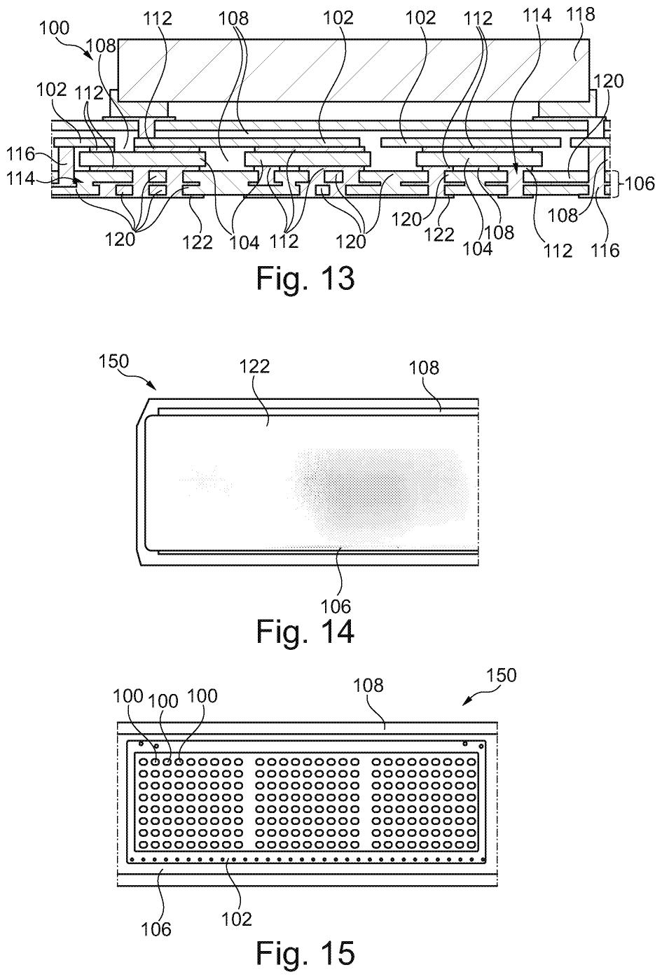

FIG. 13 illustrates a cross-sectional view of a package 100 according to another exemplary embodiment. Package 100 of FIG. 13 comprises a further electronic component 118 surface mounted on the encapsulant 108 and electrically coupled with the encapsulated electronic components 104. More specifically, FIG. 13 illustrates an embodiment in which the package 100 is configured as half bridge with driver chip realized with redistribution layer 114 and via connections. A passive component (for instance a coil) or an active component (such as a light-emitting diode, a laser diode, or a semiconductor die) or a further package (for instance a further package 100 according to an exemplary embodiment, as described herein) may be provided as further electronic component 118 on top.

FIG. 14 illustrates a main surface of a batch 150 of still integrally connected packages 100 according to another exemplary embodiment, said main surface being covered by a copper foil 122. FIG. 15 illustrates the main surface of the batch 150 of packages 100 according to FIG. 14 after removing the mentioned copper foil 122 by etching.

Thus, FIG. 14 and FIG. 15 show various packages 100 manufactured on panel level and being still connected. In the shown embodiment, each of the packages 100 corresponds to a half bridge configuration, as described above. The prepreg material of the laminate body 106 is semitransparent, so that in FIG. 15, a surrounding frame structure of the carrier 102 can be seen as well as metallic portions of the individual packages 100.

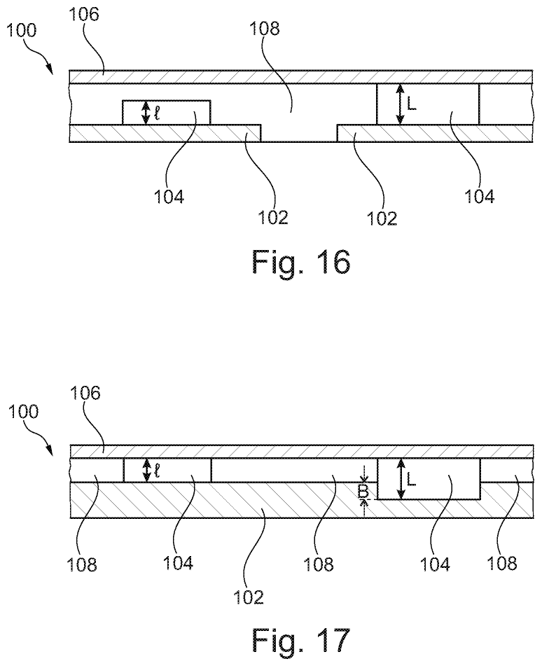

FIG. 16 illustrates a cross-sectional view of a package 100 according to still another exemplary embodiment with embedded components 104 having different vertical thickness l, L. Hence, the package 100 may comprise a plurality of electronic components 104 with different thicknesses, in the present case L>l, mounted on the same carrier 102. According to FIG. 16, bottom surfaces of the components 104 are mounted at the same vertical level of planar carrier 102. However, in accordance with the different thicknesses L, l, only one of the electronic components 104 is mounted in contact with the laminate body 106. According to FIG. 16, the lower main surfaces, but not the upper main surfaces, of the electronic components 104 are aligned.

FIG. 17 illustrates a cross-sectional view of a package 100 according to yet another exemplary embodiment in which embedded components 104 have different vertical thicknesses l, L. Also according to FIG. 17, the package 100 comprises electronic components 104 with different thicknesses, L>l, mounted on the same carrier 102. However, according to FIG. 17, the electronic components 104 with the different thicknesses l, L are mounted on different vertical levels of the carrier 102. For this purpose, carrier 102 is provided with a recess in which the electronic component 104 with the larger thickness, L, is inserted. A depth, B, of the recess fulfils the equation B=L−l. The electronic component 104 with the smaller thickness, l, is mounted on a planar portion of the carrier 102. Thus, the recess balances out the thickness differences between the electronic components 104 with different thicknesses l, L and thus ensures that the upper main surfaces of the electronic components 104 can both be in direct contact with the planar laminate body 106. According to FIG. 17, the upper main surfaces, but not the lower main surfaces, of the electronic components 104 are aligned.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

What is claimed is:

1. A package, comprising:
a carrier;
at least one electronic component mounted on the carrier;
a laminate body attached to the at least one electronic component; and
an encapsulant filling at least part of spaces between the laminate body and the carrier with the mounted at least one electronic component in between.

2. The package according to claim 1, wherein the carrier is a structured plate-shaped carrier, in particular comprises a leadframe or a patterned printed circuit board.

3. The package according to claim 1, wherein the laminate body comprises a sheet comprising a dielectric material, in particular comprises or consists of at least one of the group consisting of a prepreg layer, and a Resin Coated Copper sheet.

4. The package according to claim 1, comprising one of the following features:
the at least one electronic component comprises at least one pad exclusively on a main surface facing the carrier;
the at least one electronic component comprises at least one pad exclusively on a main surface facing the laminate body;
the at least one electronic component comprises at least one pad on a main surface facing the carrier and comprises at least one further pad on another main surface facing the laminate body;
the at least one electronic component comprises at least one pad arranged face-up;
the at least one electronic component comprises at least one pad arranged face-down.

5. The package according to claim 1, comprising one of the following features:
wherein the encapsulant extends vertically beyond, in particular completely covers, a main surface of the carrier opposing another main surface of the carrier on which the at least one electronic component is mounted,
wherein at least part of a main surface of the carrier opposing another main surface of the carrier on which the at least one electronic component is mounted is exposed with respect to the encapsulant.

6. The package according to claim 1, wherein the laminate body comprises a sheet comprising a dielectric material and comprises a metal layer on the sheet, and wherein the sheet is arranged between the metal layer and the at least one electronic component.

7. The package according to claim 1, comprising a redistribution layer, in particular a plurality of redistribution layers, formed on and/or in the laminate body.

8. The package according to claim 1, comprising at least one vertical electric connection element each extending through at least part of the encapsulant and through at least part of the laminate body, and in particular electrically coupling the laminate body with the carrier.

9. The package according to claim 1, comprising at least one of the following features:
wherein a carrier thickness is in a range between 20 μm and 3 mm;
wherein a laminate body thickness is in a range between 10 μm and 150 μm;
wherein an at least one electronic component ss is in a range between 15 μm and 1 mm; and
wherein the carrier thickness is larger than the laminate body thickness and is larger than at least one component thickness, wherein the carrier thickness is larger than the laminate body thickness and the at least one electronic component thickness together.

10. The package according to claim 1, comprising at least one further electronic component, in particular at least one of an active component and a passive component, mounted on or above the encapsulant or the carrier, and in particular being electrically coupled with the at least one encapsulated electronic component.

11. The package according to f claim 1, wherein the carrier comprises at least one opening which is at least partially filled with the encapsulant.

12. The package according to claim 1, comprising one of the following features:
the package comprises an intermixed transition portion at an interface between the laminate body and the encapsulant, wherein the intermixed transition portion comprises a mixture of material of the laminate body and the encapsulant, in particular in such a way that the intermixed transition portion bridges pure laminate body material with respect to pure encapsulant material;
the package comprises an adhesion promoter at an interface between the laminate body and the encapsulant for promoting adhesion between material of the laminate body and material of the encapsulant.

13. The package according to claim 1, comprising a plurality of electronic components, in particular with at least two different thicknesses, mounted on the carrier.

14. The package according to claim 13, comprising at least one of the following features:
wherein the plurality of electronic components with the at least two different thicknesses are mounted on different vertical levels of the carrier;
wherein only a part of the plurality of electronic components with the at least two different thicknesses is mounted in contact with the laminate body.

15. A method of manufacturing a package, wherein the method comprises:
mounting at least one electronic component on a carrier;
attaching a laminate body to the at least one electronic component; and
filling at least part of spaces, between the laminate body and the carrier with the mounted at least one electronic component in between, with an encapsulant.

16. The method according to claim 15, wherein the filling comprises one of the group consisting of molding, in particular vacuum molding, and printing, in particular one of the group consisting of ink-jet printing, stencil printing and screen printing.

17. The method according to claim 15, wherein the method comprises:
arranging the laminate body, attached to the at least one electronic component mounted on the carrier, at an encapsulation tool;
injecting a precursor of the encapsulant into an encapsulation volume defined by the encapsulation tool;
subsequently curing the precursor.

18. The method according to claim 15, wherein the method comprises manufacturing a plurality of packages by a batch fabrication.

19. The method according to claim 15, comprising one of the following features:
wherein said filling is carried out after said attaching and after said mounting;
wherein said filling is carried out before said attaching and after said mounting.

20. The method according to claim 15, comprising at least one of the following features:
wherein at the beginning of said filling, material of the encapsulant and material of the laminate body are both not yet cured;
wherein the method comprises filling at least part of the spaces by supplying a precursor of the encapsulant through at least one opening extending through the carrier.
